(19) United States
(12) Patent Application Publication
(10) Pub. No.: US 2018/0047647 A1
(43) Pub. Date: Feb. 15, 2018

(54) ANALYSIS METHOD FOR SILANOL GROUP OF SUBSTRATE SURFACE

(71) Applicant: Tokyo Electron Limited, Tokyo (JP)

(72) Inventors: Miyako Kaneko, Nirasaki City (JP); Naotaka Noro, Nirasaki City (JP)

(21) Appl. No.: 15/673,599

(22) Filed: Aug. 10, 2017

(30) Foreign Application Priority Data
Aug. 12, 2016 (JP) 2016-158530

(51) Int. Cl. H01L 21/66; H01L 21/3205; C23C 16/455; C23C 16/34; C09D 1/00; G01N 31/22

(52) U.S. Cl. CPC H01L 22/20; C09D 1/00; G01N 31/22; C23C 16/45525; C23C 16/34; H01L 21/32051; H01L 21/02164

(57) ABSTRACT

A silanol group on a surface of a substrate having silicon on the surface thereof can be quantitatively analyzed with high accuracy. An analysis method for a silanol group on a substrate surface includes chemically modifying the silanol group by supplying a gas of a metal compound to a substrate having silicon on a surface thereof and allowing the gas of the metal compound to react with the silanol group existing on the surface of the substrate; measuring a concentration of a metal contained in the metal compound which is adsorbed to the surface of the substrate; and calculating a concentration of the silanol group based on the measured concentration of the metal and a ratio in which the metal compound is allowed to be adsorbed to the silanol group on the substrate surface.

### CROSS-REFERENCE TO RELATED APPLICATION

This application claims the benefit of Japanese Patent Application No. 2016-158530 filed on Aug. 12, 2016, the entire disclosures of which are incorporated herein by reference.

### TECHNICAL FIELD

The embodiments described herein pertain generally to an analysis method for a silanol group on a substrate surface.

### BACKGROUND

In a manufacturing process of a semiconductor device, a preset film is formed on a substrate having a silicon-containing material such as a SiO₂ film on a surface thereof by chemical vapor deposition (CVD) or atomic layer deposition (ALD). For example, forming a metal containing film (e.g., titanium nitride film: TiN) on a SiO₂ film of a substrate by CVD or ALD is known as well-known technology.

According to the present inventors, it is found out that, when forming a Ti-based film such as the TiN on the SiO₂ film by the CVD or the ALD, the film formation progresses through a condensation reaction of a TiCl₄ gas used as a Ti source gas with a silanol group on a surface of the SiO₂ film. Accordingly, if a large amount of silanol group exists on the surface of the substrate which is made of the SiO₂ film or the like and on which the Ti-based film is to be formed, it may be possible to form the Ti-based film having high continuity. That is, the amount of the silanol group largely affects a film-forming property of the Ti-based film. Further, besides the case of having the SiO₂ film, if the surface of the substrate contains Si, there exists the silanol group on the surface of the substrate. Further, if the target film is formed by the CVD or the ALD, the silanol group may have a large effect on the film-forming property regardless of whether the target film is the Ti-based film or any of various other kinds of films. In view of these, it is found out that analyzing the silanol group on the substrate surface is an effective way to investigate the film-forming property.

As a method of measuring the silanol group formed on the surface of the substrate, there is known a time-of-flight secondary ion mass spectrometry (ToF-SIMS), chemical modification XPS, or the like. The ToF-SIMS is a method of irradiating an ion beam (primary ions) to a solid sample and mass-separating ions (secondary ions) released from a surface of the solid sample by using a flight time difference (flight time is proportionate to a square root of weight). Further, the chemical modification XPS is a method of performing chemical modification with a reagent, which contains a heteroatom such as fluorine suitable for XPS (X-ray photoelectron spectroscopy) analysis, and of converting a quantitative result of an introduced marker element to an amount of a functional group (silanol group).

However, though the ToF-SIMS can roughly estimate the amount of the silanol group by an ion count, quantitativeness is still not sufficient. Further, in the chemical modification XPS, since a molecular weight of the reagent used in the chemical modification is large, steric hindrance is also large, so that the quantitativeness is not sufficiently high in this case, either. As stated, conventionally, there is no method of quantitatively analyzing the silanol group on the substrate surface accurately.

### SUMMARY

In view of the foregoing, exemplary embodiments provide an analysis method for a silanol group on a substrate surface, capable of quantitatively analyzing the silanol group on a surface of a substrate having silicon on the surface thereof with high accuracy.

In an exemplary embodiment, there is provided an analysis method for a silanol group on a substrate surface, which analyzes the silanol group on a surface of a substrate having silicon on the surface thereof. The analysis method includes chemically modifying the silanol group by supplying a gas of a metal compound to the substrate and allowing the gas of the metal compound to react with the silanol group existing on the surface of the substrate; measuring a concentration of a metal contained in a reactant which is adsorbed to the surface of the substrate by the chemically modifying; and calculating a concentration of the silanol group based on the measured concentration of the metal and a ratio in which the metal compound is allowed to be adsorbed to the silanol group on the substrate surface.

Here, a SiO₂ film, a SiN film or a Si film may be formed on the surface of the substrate. The SiO₂ film may be a thermal oxide film or a plasma oxide film. The substrate may be a silicon wafer.

The metal compound may be a chloride. The metal compound may be a metal compound used in film formation by ALD or CVD. The metal compound may be TiCl₄. The silanol group and the TiCl₄ may be reacted in a temperature range from 90° C. to 600° C.

The gas of the metal compound may be supplied in a single pulse. Further, the concentration of the metal may be measured by a total reflection X-ray fluorescence (TXRF) analysis or an inductively coupled plasma mass spectrometry (ICP-MS).

The ratio in which the metal compound is allowed to be adsorbed to the silanol group on the surface substrate may be calculated from a surface density of the silicon on the substrate surface and a saturated adsorption concentration which is based on a molecular radius of the metal compound.

The chemically modifying of the silanol group is performed by allowing the gas of the metal compound to react with the silanol group existing on the surface of the substrate and then supplying a material which reacts with the metal compound.

According to the exemplary embodiment, the silanol group is chemically modified by supplying the gas of the metal compound such as TiCl₄ to the substrate and adsorbing the metal compound to the silanol group on the substrate surface. Thereafter, the concentration of the metal contained in the reactant adsorbed by the chemical modification is measured, and then, the concentration of the silanol group on the substrate surface is calculated based on the concentration of the metal and the ratio in which the metal compound is allowed to be adsorbed to the silanol group of the substrate surface. Accordingly, the metal compound can be adsorbed in the amount corresponding to the amount of the silanol group of the substrate surface. Further, since the metal is analyzed by such a method as the TXRF or the ICP-MS, the metal can be analyzed with high accuracy. Furthermore, since the metal compound used in the chemical modification only needs to be one having a small molecular weight, such as the TiCl₄, the steric hindrance can be reduced as compared to the chemical modification XPS. As a result, the amount of the silanol group can be calculated accurately, and it is possible to quantitatively analyze the silanol group of the substrate surface having the silicon with higher accuracy.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a reaction model in case of forming a TiN film, by ALD or CVD, on a SiO₂ film in a state that the SiO₂ film is only formed without any surface processing;

FIG. 2 is a diagram illustrating a reaction model in case of forming the TiN film, by the ALD or the CVD, on a SiO₂ film on which a surface processing is performed with a fluid containing O and H;

FIG. 3 is a flowchart for describing an analysis method for a silanol group on a substrate surface according to an exemplary embodiment;

FIG. 4 is a diagram illustrating a state of a reaction between Si-OH as the silanol group on the substrate surface and TiCl₄ as a metal compound;

FIG. 5 is a diagram illustrating a regular tetrahedral structure forming a crystal of the SiO₂ film;

FIG. 6 is a diagram illustrating multiple crystal structures of SiO₂;

FIG. 7 is a diagram illustrating a molecular structure and an interatomic distance of TiCl₄;

FIG. 8 is a diagram schematically illustrating arrangement of Si atoms and TiCl₄ molecules in case of adsorbing TiCl₄ to a thermal oxide film; and

FIG. 9 is a diagram illustrating an analysis result of a Ti concentration with ICP-MS after adsorbing TiCl₄ to a substrate surface by supplying a TiCl₄ gas in a single pulse for each of a case where a cleaning processing is performed and a case where a cleaning processing is not performed on individual substrates having a SiO₂ film formed by thermal oxidation under different conditions.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, an exemplary embodiment of the present disclosure will be explained in detail with reference to the accompanying drawings.

### Details Led to Present Disclosure

First, details led to the present disclosure will be explained.

In case of forming a TiN film on a SiO₂ film formed on a substrate surface (“a surface of a substrate) by ALD or CVD while using a TiCl₄ gas as a Ti source material and NH₃ as a nitriding gas, film formation progresses through a condensation reaction of the TiCl₄ gas with silanol groups on a surface of the SiO₂ film. From this point, the amount of the silanol groups on the film forming surface is important in the aspect of a film-forming property such as continuity of the TiN film when forming the TiN film. Thus, there has been a demand for a method capable of analyzing the silanol groups on the substrate surface quantitatively.

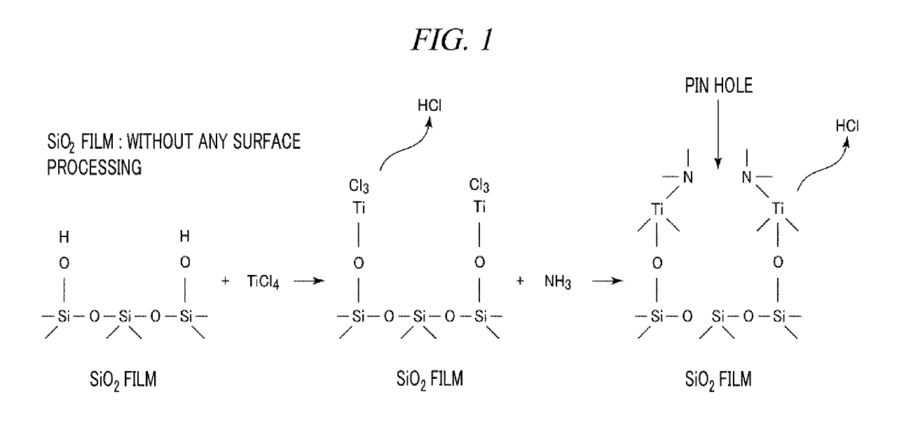

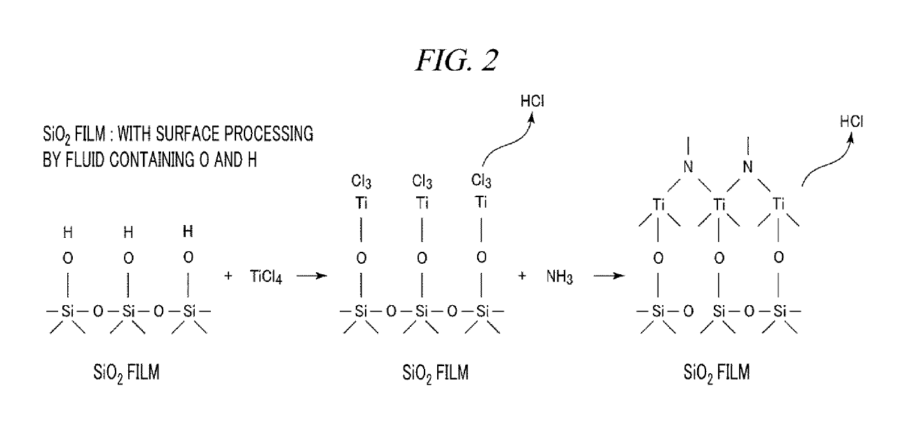

By way of example, as for the SiO₂ film which is only formed without performing any surface processing, the amount of the silanol groups (OH) on the surface thereof is not sufficient. Thus, as schematically shown in FIG. 1, there are portions on the surface of the SiO₂ film where no silanol group (OH) exists. Since the TiCl₄ does not react with those portions, if such portions are collected, there is formed a pin hole where no TiN is formed, so that the film continuity is deteriorated. Meanwhile, by performing a surface processing of bringing a fluid (a liquid or a gas) containing O and H into contact with the surface of the SiO₂ film through, for example, a wet cleaning processing of cleaning the substrate having the SiO₂ film thereon with a cleaning liquid, the silanol groups can be formed on the substantially entire surface of the SiO₂ film, as illustrated in FIG. 2.

As stated above, the amount of the silanol groups on the surface is varied depending on, for example, whether or not the surface processing is performed, which in turn determines the film-forming property of the TiN film. In view of this, if the amount of the silanol groups on the surface can be accurately analyzed in a quantitative manner, it may be possible to estimate the film-forming property of the TiN film on the substrate surface accurately before the film formation. Further, this can also be effectively used as data for evaluating a result of the film formation.

For this reason, a method of analyzing the silanol group is required. However, it is difficult to analyze the silanol group directly. Thus, it has been investigated how to analyze the silanol group indirectly.

First, a method of measuring a contact angle of the surface of the SiO₂ film is considered.

A contact angle is used as an index of hydrophilic property and hydrophobic property. Hydrophilic property accompanies a small contact angle, whereas hydrophobic property accompanies a large contact angle. Since the silanol group is hydrophilic, the contact angle decreases if the amount of the silanol groups increases. Actually, as a result of measuring the contact angle before and after the wet cleaning processing, the contact angle of the surface of the SiO₂ film before the wet cleaning is found to be about 40 deg, whereas the contact angle of the surface of the SiO₂ film after the wet cleaning is found to be 6 deg or thereabout. This measurement result shows a probability of quantitatively analyzing the silanol group based on the contact angle. If a substrate has a larger amount of pin holes formed after the TiN film formation, it may be assumed that this substrate has a smaller amount of silanol groups on a surface of a SiO₂ film. However, when actually measuring the contact angle, there is a contradiction that the substrate having the larger amount of pin holes actually has a smaller contact angle. This contradiction is deemed to be caused by other influences such as, for example, adhesion of organic materials to the substrate, besides the amount of the silanol groups. As found out from the above, although it is possible to approximately estimate whether the amount of the silanol groups is large or small based on the contact angle, it is still difficult to quantitatively analyze the silanol group with high accuracy.

Further, as stated above, ToF-SIMS is a method of irradiating the ion beam to the substrate and analyzing the silanol groups by counting fragment ions caused by the silanol groups. With this method, it can be accurately investigated whether the amount of the silanol groups is relatively large or small. Depending on a difference in estimated structures (SiO₃H₃, Si₂O₅H₃ or Si₃O₇H₃) of a compound having the silanol groups, however, the value of the ion count is greatly different. Thus, absolute quantitative analysis of the silanol group cannot be achieved with this method.

Further, in the aforementioned chemical modification XPS, since the molecular weight of the reagent used in the chemical modification is large, the steric hindrance is also large. Accordingly, it is still difficult to quantify the silanol group accurately with this method.

So, the inventors have conducted additional researches and found out that, in the same manner as in the initial film formation by the ALD, by supplying TiCl₄ as a film forming source material in a single pulse and making a condensation reaction of TiCl₄ with the silanol groups, TiCl₄ can be adsorbed in an amount corresponding to an amount of the silanol groups on the surface of the SiO₂, and by analyzing Ti of the adsorbed TiCl₄ in a method such as a total reflection X-ray fluorescence (TXRF) analysis, an inductively coupled plasma mass spectrometry (ICP-MS), or the like, the silanol groups can be quantified.

That is, by employing the method of supplying the TiCl₄ gas in the single pulse, the chemical modification can be conducted in a simpler way than the conventional chemical modification XPS while reducing the influence of the steric hindrance. Besides, the metal Ti in the adsorbed TiCl₄ can be detected by the TXRF, the ICP-MS, or the like with high accuracy. Therefore, the silanol groups can be quantitatively analyzed in a more accurate manner.

### Details of Analysis Method for Silanol Groups in Substrate Surface

Below, the analysis method will be discussed in detail.

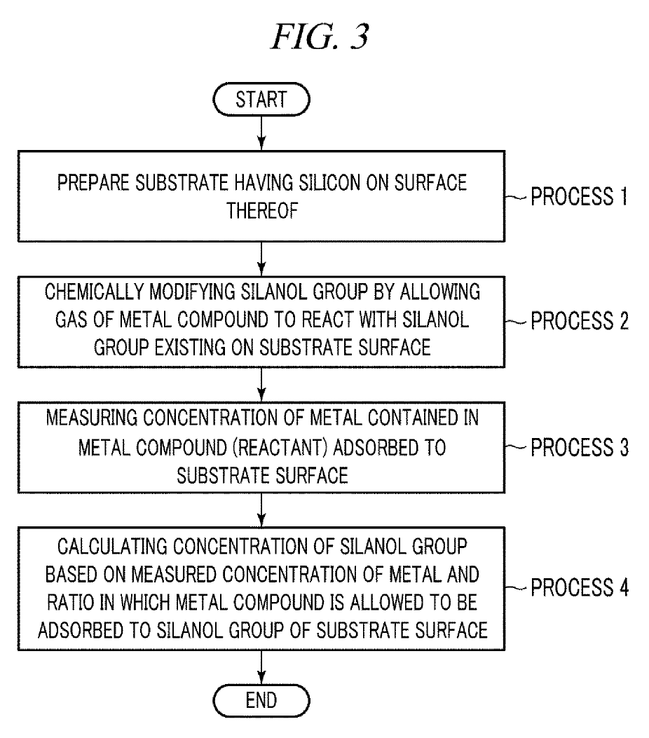

FIG. 3 is a flowchart for describing an analysis method for silanol groups on a substrate surface according to an exemplary embodiment.

First, a substrate having silicon on a surface thereof is prepared (process 1).

In the present exemplary embodiment, a substrate to be subjected to analysis of silanol groups on a surface thereof is the substrate having the silicon on the surface thereof. Since a silanol group is formed as a result of a bond of OH to Si, presence of the silicon is a premise of the formation of the silanol group. Such a substrate may be implemented by a substrate having a SiO₂ film, a SiN film or a Si film on a surface thereof, for example, a substrate (semiconductor wafer) having such a film on a semiconductor base made of silicon or the like. A thermal oxide film or a plasma oxide film may be used as the SiO₂ film. Besides these dry oxide films, a wet oxide film formed by wet oxidation may be used. Further, a silicon wafer may be used as the substrate.

Next, by allowing a gas of a metal compound (“metal compound gas”) to react with the silanol group existing on the substrate surface, the silanol group is chemically modified (process 2).

As the metal compound gas, one which makes the condensation reaction with the silanol group may be used. A metal chloride such as TiCl₄ or AlCl₃ may be appropriately used as the metal compound.

This processing can be performed by maintaining a vacuum level of the inside of a chamber in which the substrate is held, heating the substrate to a preset temperature, and supplying the metal compound into the chamber in a pulse shape one time (single pulse). Accordingly, the condensation reaction of the supplied metal compound gas with the silanol group on the substrate surface is made, and the metal compound (reactant) adsorbs to the substrate surface in an amount corresponding to the amount of the silanol groups on the substrate surface, so that the chemical modification of the silanol groups is performed.

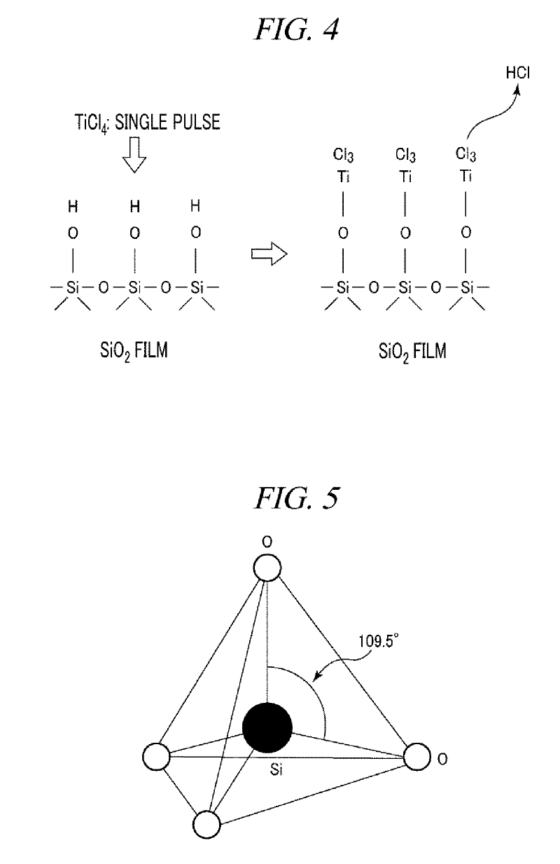

By way of example, as illustrated in FIG. 4, the silanol group of Si-OH on the substrate surface and the metal compound of TiCl₄ make the condensation reaction of the following expression (1), so that the silanol group is chemically modified by the TiCl₃.

Si—OH+TiCl₄→Si—O—TiCl₃+HCl (1)

Here, it is desirable to use a metal compound which is used in the film formation by the ALD or the CVD as the metal compound. That is, in case of forming a Ti-based film such as a TiN film by the ALD or the CVD, it is desirable to use TiCl₄, which serves as a Ti source gas for the film formation, as the metal compound for the chemical modification. In this case, the substrate before being subjected to the film formation is placed in the chamber of a film forming apparatus, and the TiCl₄ gas is introduced into the chamber in a single pulse and is made to react with the silanol groups on the substrate surface. As a result, the TiCl₄ is adsorbed to the silanol groups on the surface of the substrate.

In case of using the TiCl₄ as the metal compound, this processing can be performed under the conditions that an internal pressure of the chamber is in the range from 400 Pa to 800 Pa (3 Torr to 6 Torr) and a temperature of the substrate is in the range from 90° C. to 600° C.

Next, as for the substrate having the silanol group chemically modified with the metal compound such as the TiCl₄ or the like, a concentration of a metal contained in the metal compound (reactant) adsorbed to the substrate surface is measured (process 3).

In the present exemplary embodiment, after the silanol groups are chemically modified with the metal compound gas such as the TiCl₄ or the like, the concentration of the metal contained in the metal compound is measured by an appropriate analysis method. By way of example, TXRF or ICP-MS may be appropriately used.

The TXRF is a method of analyzing an element on a sample surface (wafer surface) by using a phenomenon that an X-ray is totally reflected on the sample surface when the X-ray is incident on the sample surface at a very small angle. With this method, the metal contained in the chemically modified compound can be quantitatively analyzed with high accuracy. Further, with the TXRF, the element analysis can be performed on a surface basis, so that a distribution of the element on the substrate surface can be measured. Accordingly, the distribution of the silanol group on the substrate surface can be investigated.

The ICP-MS is a method of introducing an element ionized by an inductively coupled plasma (ICP) into a mass spectrometry and identifying/quantifying this element. With this method, it is possible to quantitatively analyze the metal contained in the chemically modified compound with high accuracy.

Next, a concentration of the silanol groups on the substrate surface is calculated based on the concentration of the metal measured in the process 3 and a ratio in which the metal compound can be adsorbed to the silanol groups on the substrate surface (process 4).

The metal compound such as the TiCl₄ does not adsorb to all of the silanol groups of the substrate surface but reacts with them at a preset ratio with respect to the concentration of the silanol groups due to the steric hindrance. Further, the maximum concentration of the silanol group is determined by the surface structure where the silanol group is formed.

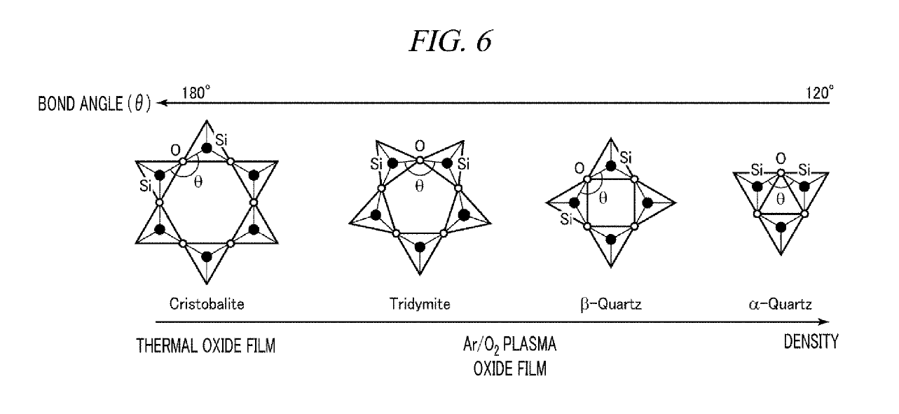

By way of example, in case that the substrate surface is the SiO₂ film, the SiO₂ film tends to be similar to a crystalline form of SiO₂. As shown in FIG. 5, the crystalline form of SiO₂ has a network structure with multiple consecutive regular tetrahedral structures, each of which consists of a single Si atom and four O atoms bonded thereto. An interatomic distance of Si—O is 1.51A. As illustrated in FIG. 6, a Si—O—Si bond angle θ varies due to crystalline structures, and a density varies as the bond angle θ decreases. That is, as compared to cristobalite having a bond angle θ of 180° at maximum, has a density of about 2.2 g/cm³, α-Quartz having a bond angle θ of 120° has a density of about 2.7 g/cm³.

If the SiO₂ film is a thermal oxide film (e.g., 950° C.), a repulsive force between O²⁻ increases due to heat, and a bond angle θ tends to be enlarged. Thus, it is known that the SiO₂ film has a structure similar to the cristobalite and has a density of about 2.24 g/cm³. Meanwhile, if the SiO₂ film is a plasma oxide film formed by Ar/O₂ plasma, a Si-O network is formed at a relatively low temperature and this SiO₂ film has a structure between tridymite and β-Quartz and has a density of about 2.45 g/cm³.

When Si atom surface densities of the thermal oxide film and the plasma oxide film are calculated from their densities, they are 8.0×10¹⁴ atoms/cm² and 8.5×10¹⁴ atoms/cm², respectively. Since the silanol group has a structure with Si and OH bonded thereto, maximum surface densities of the silanol groups of the thermal oxide film and the plasma oxide film are respectively 8.0×10¹⁴ atoms/cm² and 8.5×10¹⁴ atoms/cm², the same as the Si atom surface densities.

In case of the thermal oxide film, assuming that the Si atom is located at the apex of an equilateral triangle, the interatomic distance of Si-Si is estimated to be 3.7A from the aforementioned calculation result of the Si atom surface density.

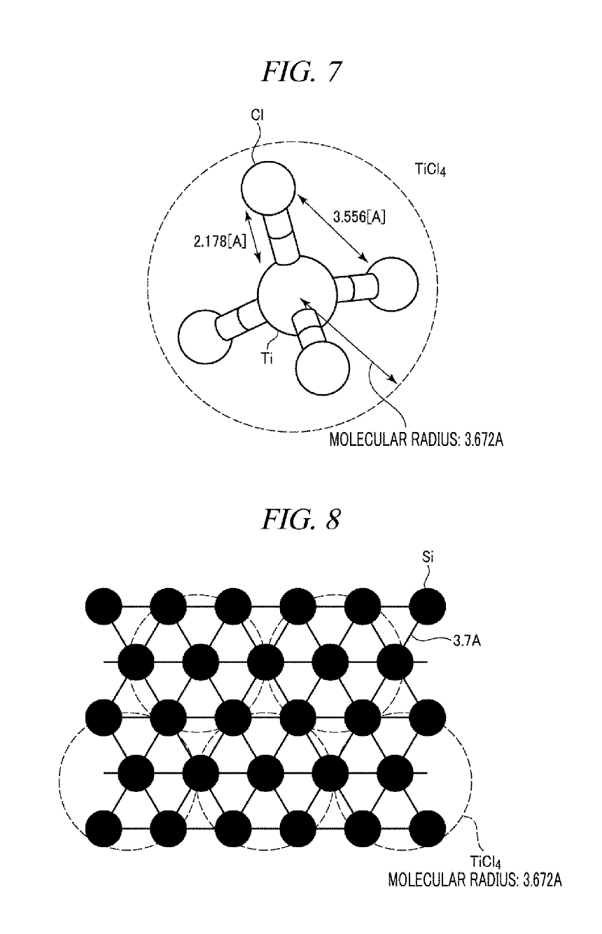

Meanwhile, in case of using the TiCl₄ as the metal compound for the chemical modification, a molecular structure and the interatomic distance of the TiCl₄ are as illustrated in FIG. 7. That is, a molecular radius of the TiCl₄ is 3.672A, which is substantially equal to the Si-Si interatomic distance of the thermal oxide film.

Accordingly, as illustrated in FIG. 8, a single molecule of TiCl₄ can be adsorbed to approximately seven Si atoms of the thermal oxide film. That is, considering that the maximum surface density of the silanol group on the thermal oxide film is 8.0×10¹⁴ atoms/cm², a saturated adsorption density (maximum surface density) of the TiCl₄ becomes 1.2×10¹⁴ atoms/cm² equivalent to 14% of the maximum surface density of the silanol group.

Thus, the concentration of the silanol group can be calculated by multiplying the concentration of the metal in the metal compound calculated in the process 3, that is, the concentration of Ti in the present example and a ratio between the maximum surface density of the silanol group and the saturated adsorption concentration of the TiCl₄, that is, 8/1.2. That is, the silanol group on the substrate surface can be quantitatively analyzed.

As stated above, in the present exemplary embodiment, by supplying the metal compound gas to the substrate in a single pulse, the metal compound such as the TiCl₄ is adsorbed to the silanol group of the substrate surface, so that the silanol group is chemically modified. Further, the concentration of the metal contained in the adsorbed metal compound (reactant) is measured, and then, the concentration of the silanol group on the substrate surface is calculated based on the concentration of the metal and the ratio in which the metal compound is allowed to be adsorbed to the silanol group of the substrate surface. Accordingly, the metal compound can be adsorbed in the amount corresponding to the amount of the silanol group of the substrate surface. Further, since the metal is analyzed by such a method as the TXRF or the ICP-MS, the metal can be analyzed with high accuracy. Furthermore, since the metal compound used in the chemical modification only needs to be one having a small molecular weight, such as the TiCl₄, the steric hindrance can be reduced as compared to the chemical modification XPS. Thus, the amount of the silanol group can be calculated accurately. Therefore, it is possible to quantitatively analyze the silanol group of the substrate surface having the silicon.

When the film formation is performed by the ALD or the CVD, the silanol groups of the substrate surface react with the film forming source gas to contribute to the film formation. Thus, if a large amount of silanol group exists on the substrate surface, the continuity of the film can be improved and, besides, the uniformity of the film can also be bettered because the formation of the pin hole is suppressed. Therefore, by analyzing the silanol group of the substrate surface, the film-forming property when forming the film by the ALD or the CVD can be investigated, which greatly contributes to the development of the film forming method.

### Experimental Example

Now, an experimental example will be explained.

Here, substrates (samples 1 and 2) respectively having the SiO₂ films formed by the thermal oxidation under different conditions are prepared, and the analysis of the silanol group is conducted for a case where the cleaning processing is performed on these substrates and a case where the cleaning processing is not performed thereon.

Further, the cleaning processing is performed with SC1 (ammonia/hydrogen peroxide) for both the samples 1 and 2. Further, the SiO₂ film of the sample 1 is formed by dry oxidation, whereas the SiO₂ film of the sample 2 is formed by wet oxidation.

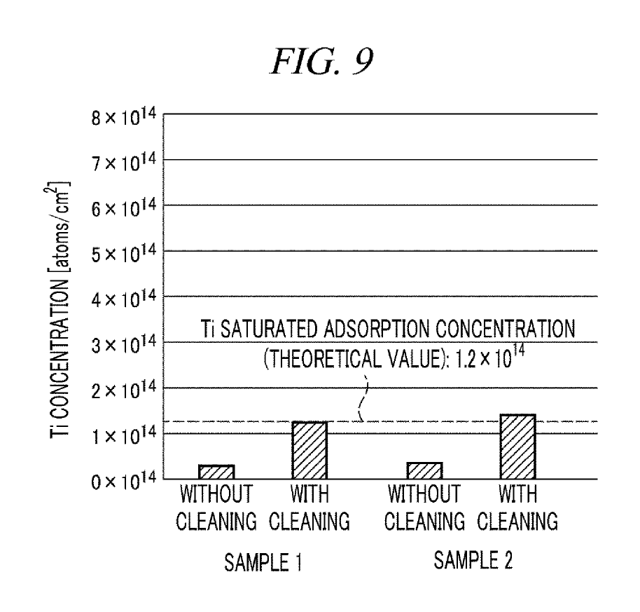

By supplying the TiCl₄ gas to these substrates in a single pulse at a temperature of 530° C., the TiCl₄ gas is adsorbed to substrate surfaces, and the Ti concentrations are analyzed by the ICP-MS. Results are shown in FIG. 9.

As can be seen from FIG. 9, the Ti adsorption concentration of the samples 1 and 2 without the cleaning processing is found to be 0.23×10¹⁴ atoms/cm². The concentration of the silanol group calculated from this Ti adsorption concentration value is found to be 1.53×10¹⁴ atoms/cm².

On the other hand, with the cleaning processing, the Ti concentration is increased, so that the Ti concentrations of both samples show a value equal to or higher than the calculated Ti saturated adsorption concentration of 1.2×10¹⁴ atoms/cm². From this result, it is found out that the silanol group is given a value close to the maximum surface density of 8×10¹⁴ atoms/cm² through the cleaning processing.

In view of the foregoing, by analyzing the silanol group based on the present disclosure, it is found out that the amount of the silanol group is increased through the cleaning processing.

### Another Applications

From the foregoing, it will be appreciated that the exemplary embodiment of the present disclosure has been described herein for purposes of illustration, and that various modifications may be made without departing from the scope and spirit of the present disclosure. Accordingly, the embodiment disclosed herein is not intended to be limiting. The scope of the inventive concept is defined by the following claims and their equivalents rather than by the detailed description of the exemplary embodiment. It shall be understood that all modifications and embodiments conceived from the meaning and scope of the claims and their equivalents are included in the scope of the inventive concept.

By way of example, in the above-described exemplary embodiment, the TiCl₄ is supplied in the single pulse as the metal compound for chemically modifying the silanol group. However, a metal compound containing a metal besides the Ti or a chloride may be used instead. Further, when chemically modifying the silanol group, it may be also possible to first supply the metal compound in a single pulse and then supply the material which reacts with the metal compound. That is, after supplying the TiCl₄ in a single pulse, the nitriding may be performed by supplying a nitriding gas such as NH₃ in a single pulse. It is deemed that the metal compound is in a more stable state by supplying the material which reacts with the metal compound.

We claim:

1. An analysis method for a silanol group on a substrate surface, which analyzes the silanol group on a surface of a substrate having silicon on the surface thereof, the analysis method comprising:
chemically modifying the silanol group by supplying a gas of a metal compound to the substrate and allowing the gas of the metal compound to react with the silanol group existing on the surface of the substrate;
measuring a concentration of a metal contained in a reactant which is adsorbed to the surface of the substrate by the chemically modifying; and
calculating a concentration of the silanol group based on the measured concentration of the metal and a ratio in which the metal compound is allowed to be adsorbed to the silanol group on the substrate surface.

2. The analysis method of claim 1,
wherein a SiO₂ film, a SiN film or a Si film is formed on the surface of the substrate.

3. The analysis method of claim 2,
wherein the SiO₂ film is a thermal oxide film or a plasma oxide film.

4. The analysis method of claim 1,
wherein the substrate is a silicon wafer.

5. The analysis method of claim 1,
wherein the metal compound is a chloride.

6. The analysis method of claim 1,
wherein the metal compound is a metal compound used in film formation by ALD or CVD.

7. The analysis method of claim 5,
wherein the metal compound is TiCl₄.

8. The analysis method of claim 7,
wherein the silanol group and the TiCl₄are reacted in a temperature range from 90° C. to 600° C.

9. The analysis method of claim 1,
wherein the gas of the metal compound is supplied in a single pulse.

10. The analysis method of claim 1,
wherein the concentration of the metal is measured by a total reflection X-ray fluorescence (TXRF) analysis or an inductively coupled plasma mass spectrometry (ICP-MS).

11. The analysis method of claim 1,
wherein the ratio in which the metal compound is allowed to be adsorbed to the silanol group on the surface substrate is calculated from a surface density of the silicon on the substrate surface and a saturated adsorption concentration which is based on a molecular radius of the metal compound.

12. The analysis method of claim 1,
wherein the chemically modifying of the silanol group is performed by allowing the gas of the metal compound to react with the silanol group existing on the surface of the substrate and then supplying a material which reacts with the metal compound.
